(19) United States
(12) Patent Application Publication
(10) Pub. No.: US 2021/0408764 A1
(43) Pub. Date: Dec. 30, 2021

(54) LASER DIODE AND METHOD FOR PRODUCING LASER RADIATION OF AT LEAST TWO FREQUENCIES

(71) Applicant: OSRAM Opto Semiconductors GmbH, Regensburg (DE)

(72) Inventor: Jens EBBECKE, Rohr In Niederbayern (DE)

(21) Appl. No.: 17/291,083

(22) PCT Filed: Oct. 30, 2019
(86) PCT No.: PCT/EP2019/079631

§ 371 Date: May 4, 2021

(30) Foreign Application Priority Data
Nov. 7, 2018 (DE) 10 2018 127 760.1

(51) Int. Cl. H01S 5/10; H01S 5/125; H01S 5/12

(52) U.S. Cl. CPC H01S 5/1096; H01S 5/125; H01S 5/34; H01S 5/1228; H01S 5/1003

(57) ABSTRACT

The invention relates to laser diode for generating laser radiation of at least two frequencies, comprising: a semiconductor body having a ridge waveguide; a DFB structure or DBR structure in the ridge waveguide; and a piezoelectric element for producing mechanical stress in the ridge waveguide, which piezoelectric element is arranged on the ridge waveguide. The invention further relates to a method for producing laser radiation of at least two frequencies by means of the laser diode.

### CROSS REFERENCE TO RELATED APPLICATIONS

This patent application is a national stage entry from International Application No. PCT/EP2019/079631, filed on Oct. 30, 2019, published as International Publication No. WO 2020/094473 A1 on May 14, 2020, and claims priority under 35 U.S.C. § 119 from German patent application 10 2018 127 760.1, filed Nov. 7, 2018, the entire contents of all of which are incorporated by reference herein.

### FIELD

The application relates to a laser diode suitable for generating laser radiation of at least two frequencies, and to a method for generating laser radiation of at least two frequencies with the laser diode.

### BACKGROUND

Laser radiation of at least two different frequencies emitted by a single laser system has a wide variety of applications, for example, in sensors, in atomic clocks, or in spectroscopy. However, such laser systems, which are suitable for generating laser radiation of two different frequencies, are usually comparatively complex and therefore not readily suitable for use in mass products.

### SUMMARY

The invention is based on the object of specifying a laser light source which is suitable for the simultaneous emission of laser radiation of two different frequencies and which can be manufactured comparatively simply and inexpensively. Furthermore, a method for generating laser radiation with the laser diode is to be specified.

These objects are solved by a laser diode and by a method according to the independent patent claims. Advantageous embodiments and further developments of the invention are the subject of the dependent claims.

According to at least one embodiment, the laser diode comprises a semiconductor body with a ridge waveguide. The semiconductor body comprises a semiconductor layer sequence which comprises, in particular, an n-type semiconductor region, a p-type semiconductor region and an active layer arranged between the n-type semiconductor region and p-type semiconductor region and suitable for emitting laser radiation. The p-type semiconductor region, the n-type semiconductor region, and the active layer may each include one or more semiconductor layers. The p-type semiconductor region includes one or more p-doped semiconductor layers, and the n-doped semiconductor region includes one or more n-doped semiconductor layers. It is also possible that the p-type semiconductor region and/or the n-type semiconductor region include one or more undoped semiconductor layers.

For example, the active layer may be formed as a pn junction, a double heterostructure, a single quantum well structure, or a multiple quantum well structure. The term quantum well structure includes any structure in which charge carriers undergo quantization of their energy states by confinement.

In particular, the term quantum well structure does not contain any indication of the dimensionality of the quantization. It thus includes, inter alia, quantum wells, quantum wires and quantum dots, and any combination of these structures.

In particular, the semiconductor layer sequence may be epitaxially grown on a substrate. For example, in the laser diode, the n-type semiconductor region faces the substrate and the p-type semiconductor region faces away from the substrate. In particular, the laser diode is an edge-emitter laser diode comprising a laser resonator whose resonator axis is parallel to the layer plane of the active layer. In such an edge-emitter laser diode, the laser resonator is formed by two laser facets which are side flanks of the semiconductor body. It is possible that at least one or both side flanks of the semiconductor body forming the laser facets are provided with a reflection-increasing coating.

According to at least one embodiment, the laser diode comprises a ridge waveguide formed, for example, in the p-type semiconductor region. The ridge waveguide can be generated, for example, by an etching process in which the semiconductor body is narrowed from the surface, in particular in the p-type semiconductor region, to form a ridge. In particular, the ridge waveguide is formed by a ridge extending in the direction of the laser cavity of the laser diode. The width of the ridge waveguide, i.e., the extent perpendicular to the resonator axis, may be, for example, between 1 μm and 10 μm.

According to at least one embodiment, the ridge waveguide comprises a distributed feedback (DFB) structure or a distributed Bragg reflection (DBR) structure. In particular, the laser diode is a so-called DFB laser or DBR laser. The DFB or DBR structure can be a structure generated at the surface of the ridge waveguide, in particular periodic at least in regions, by which a modulation of the refractive index of the semiconductor material along the resonator axis is generated. The DFB or DBR structure is formed, for example, by a sequence of elevations and depressions along the resonator axis in the ridge waveguide.

According to at least one embodiment, a piezoelectric element is arranged on the ridge waveguide. The piezoelectric element is adapted to exert a mechanical force by applying an electrical voltage and, in this way, generate a mechanical stress in the ridge waveguide. In particular, the piezoelectric element is a layer of piezoelectric material arranged between two electrodes. Piezoelectric materials are characterized by the fact that an electrical voltage is generated by the application of pressure, and that, conversely, the application of an electrical voltage can cause deformation. This inverse piezoelectric effect is exploited in the laser diode described here to apply a force to the ridge waveguide by applying an electrical voltage, resulting in a mechanical stress in the ridge waveguide. In particular, the mechanical stress causes the ridge waveguide to have a birefringent property in the region of the piezoelectric element.

The laser diode described herein makes use of the idea that the mechanical stress generated in the ridge waveguide by the piezoelectric element causes the semiconductor material to become birefringent. In other words, the refractive index in the semiconductor material becomes dependent on the polarization direction of the radiation. During operation of the laser diode, this results in the laser resonator in the generation of two different laser modes with different polarization directions, which comprise two different frequencies.

The laser diode is thus in particular suitable for simultaneously emitting laser radiation of a first frequency and laser radiation of a second frequency different from the first frequency when an electrical voltage is applied to the piezoelectric element. When the electrical voltage to the piezoelectric element is turned off, the ridge waveguide loses its bipolar characteristic so that laser radiation of a single frequency is emitted. The laser diode can therefore advantageously emit either radiation of two frequencies or radiation of a single frequency depending on the applied electrical voltage.

Advantageously, the frequency difference between the first frequency and the second frequency can be varied by the absolute value of electrical voltage applied to the piezoelectric element. In particular, the greater the electrical voltage applied to the piezoelectric element, the greater the mechanical stress in the ridge waveguide and thus the stronger its birefringent property.

According to at least one embodiment, the voltage applied to the piezoelectric element is a DC voltage. The DC voltage may comprise a positive or negative sign. For example, the DC voltage comprises an absolute value between 0.1 V and 300 V, preferably between 10 V and 100 V.

According to at least one embodiment, a frequency difference between the first frequency and the second frequency is between 1 kHz and 1 THz, preferably in the range of 1 MHz to 1 GHz. The achievable frequency difference depends in particular on the electrical voltage applied to the piezoelectric element, the material of the piezoelectric element, the semiconductor material of the ridge waveguide, and the size of the birefringent region of the ridge waveguide defined by the size of the piezoelectric element.

According to at least one embodiment, the piezoelectric element comprises AlN, ZnO, PZT (lead zirconate titanate), LiNbO₃, KNbO₃ or LiTaO₃. These materials are characterized by their piezoelectric property and are well suited to generate a mechanical stress in the ridge waveguide.

According to at least then embodiment, the semiconductor body of the laser diode is based on an arsenide compound semiconductor. “Based on an arsenide compound semiconductor” means in the present context that the semiconductor layer sequence, in particular the active layer, comprises an arsenide compound semiconductor material, preferably AlₙGaₙIn₁₋ₙ₋ₘAs, wherein 0≤n≤1, 0≤m≤1 and n+m≤1. This material need not necessarily comprise a mathematically exact composition according to the above formula. Rather, it may comprise one or more dopants as well as additional constituents that do not substantially alter the characteristic physical properties of the AlₙGaₙIn₁₋ₙ₋ₘAs material. For simplicity, however, the above formula includes only the essential constituents of the crystal lattice (Al, Ga, In, As), even though these may be partially replaced by small amounts of other substances. If the semiconductor body is based on an arsenide compound semiconductor material, the laser diode can emit radiation in the red or infrared spectral range, for example.

Alternatively, however, the semiconductor body may comprise a different semiconductor material and/or emit in a different spectral region. For example, the semiconductor body may be based on a nitride compound semiconductor material and, in particular, emit radiation in the ultraviolet, blue, or green spectral region. It is further possible that the semiconductor body comprises, for example, a phosphide compound semiconductor material and emits visible radiation in the green, yellow or red spectral region.

A method of generating laser radiation of at least two frequencies using the laser diode described above is further specified. According to at least one embodiment, the method operates a laser diode comprising a semiconductor body having a ridge waveguide, a DFB or DBR structure in the ridge waveguide, and a piezoelectric element disposed on the ridge waveguide.

In the method, an electrical voltage is applied to the piezoelectric element to generate a mechanical stress in the ridge waveguide. In particular, the mechanical stress causes the ridge waveguide to have a birefringent property. In this way, it is achieved that the laser diode simultaneously emits laser radiation of a first frequency and a second frequency different from the first frequency.

In the method, the laser radiation of the first frequency and the second frequency is emitted in particular simultaneously from a laser facet of the laser diode. In the method, the laser radiation of two different frequencies is advantageously generated within the laser diode. In particular, no optical setup outside the laser diode is required to generate the two different frequencies, as is the case, for example, with fiber-optic systems for generating different frequencies. The laser diode is therefore particularly suitable for compact sensors in which laser radiation of two different frequencies is used.

In the method, the frequency difference between the first frequency and the second frequency is advantageously controllable by the electrical voltage applied to the piezoelectric element. The frequency difference is therefore comparatively easy to adjust. The electrical voltage is preferably a DC voltage with an absolute value in the range from 0.1 V to 10 V, particularly preferably from 10 V to 100 V.

Further advantageous embodiments of the method will result from the description of the laser diode and vice versa.

### BRIEF DESCRIPTION OF THE DRAWINGS

The invention is explained in more detail below by means of an exemplary embodiment in connection with FIG. 1.

FIG. 1 shows a schematic perspective view of an exemplary embodiment of the laser diode.

The components shown as well as the proportions of the components among each other are not to be regarded as true to scale.

### DETAILED DESCRIPTION

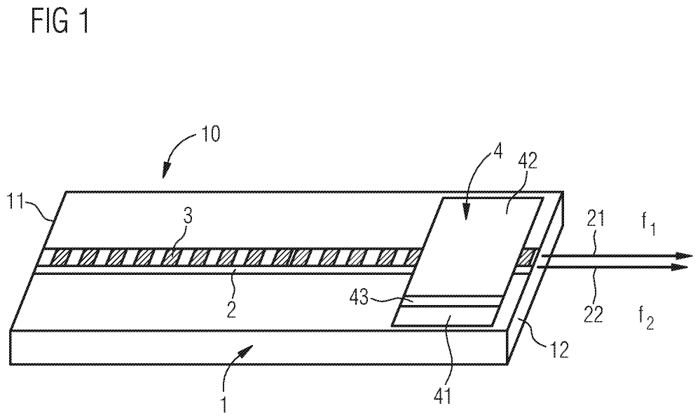

The laser diode 10 shown schematically in FIG. 1 comprises a semiconductor body 1. The semiconductor body 1 contains a semiconductor layer sequence which comprises, in particular, an n-type semiconductor region, an active layer and a p-type semiconductor region. Furthermore, the semiconductor body 1 comprises a p-type contact and an n-type contact for electrically contacting the semiconductor layer sequence. The individual layers of the semiconductor layer sequence and their contacts are not shown here for simplicity. The semiconductor layer sequence may be based on an arsenide compound semiconductor, for example.

A ridge waveguide 2 is formed at the upper side of the semiconductor body 1. The ridge waveguide 2 is formed by a ridge, which may be produced by an etching process into the p-type semiconductor region, for example. The ridge waveguide 2 extends in the direction of the resonator axis of the laser diode 10 between a first laser facet 11 and a second laser facet 12. The length of the laser resonator, i.e., the distance between the first laser facet 11 and the second laser facet 12, is between 0.5 mm and 5 mm, for example.

A DFB structure 3 is formed at the surface of the ridge waveguide 2. In particular, the DFB structure 3 is formed by a sequence of elevations and depressions in the ridge waveguide 2 and can be produced, for example, by an etching process in the ridge waveguide 2. The elevations and depressions are formed in particular in the p-type semiconductor region of the laser diode 10. In particular, the DFB structure is periodic at least in regions. As can be seen in FIG. 1, the periodicity can be interrupted, for example, in the middle of the laser resonator in order to generate a phase jump there. On the upper side of the laser diode 10, an electrically insulating layer and above it a p-contact may be arranged, wherein the electrically insulating layer comprises an opening at the upper side of the ridge waveguide 2, so that the p-contact contacts only the upper side of the ridge waveguide. The electrically insulating layer and the p-contact are not shown in FIG. 1, so that the DFB structure 3 is visible. The n-contact, which is also not shown, can be arranged on a back side of the laser diode 10. Alternatively to a DFB structure 3, the laser diode may comprise a DBR structure.

A piezoelectric element 4 is arranged on the ridge waveguide 2 having the DFB structure 3 in the laser diode 10.

The piezoelectric element 4 covers only a portion of the ridge waveguide 2, which is preferably arranged in the vicinity of the second laser facet 12 provided for coupling out radiation. In the longitudinal direction of the ridge waveguide 2, for example, the piezoelectric element 4 may comprise an extension between 50 μm and 1 mm, preferably between 100 μm and 200 μm. In the direction transverse to the ridge waveguide 2, the piezoelectric element 4 covers the ridge waveguide 2, its side flanks and at least partially also the surface of the laser diode 10 next to the ridge waveguide 2.

The laser diode 10 is preferably not electrically contacted in the region of the piezoelectric element 4, in particular the p-contact of the laser diode 10 is preferably arranged only outside the piezoelectric element 4. The area of the laser resonator located below the piezoelectric element 4 is thus not electrically pumped.

The piezoelectric element 4 comprises a first electrode 41, a second electrode 42 and a layer 43 of a piezoelectric material arranged between the first electrode 41 and the second electrode 42. In particular, the layer 43 may comprise a ceramic having piezoelectric properties. For example, the layer 43 may comprise AlN, ZnO, PZT, LiNbO₃, KNbO₃ or LiTaO₃. By applying an electrical voltage to the electrodes 41, 42, a mechanical stress can advantageously be generated in the ridge waveguide 2 in the laser diode 10. The mechanical stress generated in this way causes the ridge waveguide 2 to have a birefringent property in the region of the piezoelectric element 4. The electrical voltage is, for example, a DC voltage with an absolute value in the range from 0.1 V to 300 V, and particularly preferably in the range from 10 V to 100 V.

By means of the birefringent property of the ridge waveguide 2 generated in this way, it can be achieved that two laser modes with two different frequencies propagate in the laser resonator between the first laser facet 11 and the second laser facet 12. The two laser modes differ from each other in their polarization and frequency.

Therefore, the laser diode 10 emits from the second laser facet 12, which is the output facet in the exemplary embodiment, simultaneously a first laser radiation 21 with a first frequency f1 and a second laser radiation 22 with a second frequency f2. Advantageously, the difference between the first frequency f1 and the second frequency f2 can be selectively adjusted by the electrical voltage applied to the electrodes 41, 42. For example, the frequency difference Δf between the first frequency f1 and the second frequency f2 may be between 1 kHz and 1 THz, preferably in the range of 1 MHz to 1 GHz.

In particular, an advantage of the laser diode 10 is that the laser radiation 21, 22 of two different frequencies f1, f2 is generated directly in the laser diode 10 without the need for further optical elements outside the laser diode 10. The laser diode 10 described herein therefore provides a laser light source that is particularly suitable for applications in which laser radiation of two different frequencies is to be used in a compact setup. Therefore, one possible application of the laser diode 10 is sensors that require a laser light source of two different frequencies as a light source.

The invention is not limited by the description based on the exemplary embodiments. Rather, the invention encompasses any new feature as well as any combination of features, which in particular includes any combination of features in the patent claims, even if that feature or combination itself is not explicitly specified in the patent claims or exemplary embodiments.

1. A laser diode for generating laser radiation of at least two frequencies, comprising
a semiconductor body with a ridge waveguide,
a DFB structure or DBR structure in the ridge waveguide, and
a piezoelectric element disposed on the ridge waveguide for generating a mechanical stress in the ridge waveguide.

2. The laser diode according to claim 1,
wherein the mechanical stress causes the ridge waveguide to have a birefringent property in the region of the piezoelectric element.

3. The laser diode according to claim 1,
wherein the laser diode is adapted to simultaneously emit a first laser radiation of a first frequency and a second laser radiation of a second frequency different from the first frequency when an electric voltage is applied to the piezoelectric element.

4. The laser diode according to claim 3,
wherein the electrical voltage is a DC voltage.

5. The laser diode according to claim 3,
wherein the absolute value of the electrical voltage is between 0.1 V and 300 V.

6. The laser diode according to claim 5,
wherein the absolute value of the electrical voltage is between 10 V and 300 V.

7. The laser diode according to claim 1,
wherein a frequency difference between the first frequency and the second frequency is between 1 kHz and 1 THz.

8. The laser diode according to claim 1,
wherein the piezoelectric element comprises AlN, ZnO, PZT, LiNbO₃, KNbO₃ or LiTaO₃.

9. The laser diode according to claim 1,
wherein the semiconductor body is based on an arsenide compound semiconductor.

10. A method for generating laser radiation of at least two frequencies with a laser diode comprising a semiconductor body having a ridge waveguide, a DFB structure or DBR structure in the ridge waveguide, and a piezoelectric element arranged on the ridge waveguide,
wherein an electrical voltage is applied to the piezoelectric element to generate a mechanical stress in the ridge waveguide, and wherein the laser diode simultaneously emits a first laser radiation of a first frequency and a second laser radiation of a second frequency different from the first frequency.

11. The method according to claim 10,
wherein the first laser radiation and the second laser radiation are emitted simultaneously from a laser facet of the laser diode.

12. The method according to claim 10,
wherein a frequency difference between the first frequency and the second frequency is controllable by the electric voltage applied to the piezoelectric element.

13. The method according to claim 10,
wherein the electrical voltage is a DC voltage having an absolute value between 0.1 V and 300 V.

14. The method according to claim 10,
wherein the mechanical voltage causes the ridge waveguide to have a birefringent property in the region of the piezoelectric element.

15. The method according to claim 10,
wherein a frequency difference between the first frequency and the second frequency is between 1 MHz and 1 THz.

16. The method according to claim 10,
wherein the piezoelectric element comprises AlN, ZnO, PZT, LiNbO₃, KNbO₃ or LiTaO₃.

17. A laser diode for generating laser radiation of at least two frequencies, comprising:
a semiconductor body with a ridge waveguide;
a DFB structure or DBR structure in the ridge waveguide; and
a piezoelectric element disposed on the ridge waveguide for generating a mechanical stress in the ridge waveguide, wherein
the mechanical stress causes the ridge waveguide to have a birefringent property in the region of the piezoelectric element,
the laser diode is adapted to simultaneously emit a first laser radiation of a first frequency and a second laser radiation of a second frequency different from the first frequency when an electric voltage is applied to the piezoelectric element, and
the first laser radiation and the second laser radiation have different polarization directions.
